(19) United States
(12) Patent Application Publication
(10) Pub. No.: US 2022/0122820 A1
(43) Pub. Date: Apr. 21, 2022

(54) SUBSTRATE PROCESSING APPARATUS

(71) Applicant: Tokyo Electron Limited, Tokyo (JP)

(72) Inventor: Yoshitomo Konta, Kurokawa-gun (JP)

(21) Appl. No.: 17/504,625

(22) Filed: Oct. 19, 2021

(30) Foreign Application Priority Data
Oct. 20, 2020 (JP) 2020-175756
Oct. 6, 2021 (JP) 2021-164544

(51) Int. Cl. H01J 37/32

(52) U.S. Cl. CPC H01J 37/32834; H01J 2237/334

(57) ABSTRACT

A chamber includes a side wall and a bottom portion, and is provided with at least one gas supply port and multiple exhaust ports. Some or all of the exhaust ports are formed in the bottom portion. A substrate support is placed inside the chamber. An annular baffle plate is placed near the substrate support to cover the exhaust ports when viewed from a top, and a gap is formed between the annular baffle plate and the substrate support. A pipe unit includes a collection pipe unit, multiple first pipes and a second pipe. The collection pipe unit includes a side wall, and the side wall is provided with multiple first openings and a second opening located above the first openings. The multiple first pipes extend from the first openings to the exhaust ports, respectively. The second pipe extends from the second opening to the vacuum pump.

### CROSS-REFERENCE TO RELATED APPLICATION

This application claims the benefit of Japanese Patent Application Nos. 2020-175756 and 2021-164544 filed on Oct. 20, 2020 and Oct. 6, 2021, respectively, the entire disclosures of which are incorporated herein by reference.

### TECHNICAL FIELD

The exemplary embodiments described herein pertain generally to a substrate processing apparatus.

### BACKGROUND

Patent Document 1 discloses a substrate processing apparatus in which an exhaust port is formed at one location near an edge of a bottom surface of a chamber provided with a stage on which a substrate is to be placed and the inside of the processing chamber is decompressed by exhausting the internal atmosphere through the exhaust port.

Patent Document 1: International Patent Publication No. WO2013/175897

### SUMMARY

In one exemplary embodiment, a substrate processing apparatus includes a chamber, a substrate support, and an annular baffle plate, a vacuum pump and a pipe unit. The chamber includes a side wall and a bottom portion, and is provided with at least one gas supply port and multiple exhaust ports. Some or all of the multiple exhaust ports are formed in the bottom portion of the chamber. The substrate support is placed inside the chamber. The annular baffle plate is placed near the substrate support to cover the multiple exhaust ports when viewed from a top, and a gap is formed between the annular baffle plate and the substrate support. The pipe unit includes a collection pipe unit, multiple first pipes and a second pipe. The collection pipe unit includes a side wall, and the side wall is provided with multiple first openings and a second opening located above the multiple first openings. The multiple first pipes extend from the multiple first openings to the multiple exhaust ports, respectively. The second pipe extends from the second opening to the vacuum pump.

The foregoing summary is illustrative only and is not intended to be in any way limiting. In addition to the illustrative aspects, exemplary embodiments, and features described above, further aspects, exemplary embodiments, and features will become apparent by reference to the drawings and the following detailed description.

### BRIEF DESCRIPTION OF THE DRAWINGS

In the detailed description that follows, exemplary embodiments are described as illustrations only since various changes and modifications will become apparent to those skilled in the art from the following detailed description. The use of the same reference numerals in different figures indicates similar or identical items.

FIG. 1 is a view schematically showing a configuration example of a substrate processing apparatus according to an exemplary embodiment;

FIG. 2 is a view schematically showing a configuration example of an exhaust unit according to the exemplary embodiment;

FIG. 3 is a perspective view showing the configuration example of the exhaust unit according to the exemplary embodiment;

FIG. 4 schematically shows a carry-in of a substrate into the substrate processing apparatus according to the exemplary embodiment;

FIG. 5 shows exhaust characteristics of the substrate processing apparatus according to the exemplary embodiment;

FIG. 6 is a view schematically showing a configuration of a substrate processing apparatus according to a comparative example;

FIG. 7 shows exhaust characteristics of the substrate processing apparatus according to the comparative example;

FIG. 8 is a view schematically showing another configuration example of the substrate processing apparatus according to the exemplary embodiment; and

FIG. 9 is a view schematically showing an arrangement example of exhaust ports at a bottom wall portion of a chamber according to the another exemplary embodiment.

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current exemplary embodiment. Still, the exemplary embodiments described in the detailed description, drawings, and claims are not meant to be limiting. Other exemplary embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

Hereinafter, exemplary embodiments of a substrate processing apparatus according to the present disclosure will be described in detail with reference to the accompanying drawings. However, the present exemplary embodiments do not limit the substrate processing apparatus.

There has been known a substrate processing apparatus that processes a substrate by decompressing an inside of a chamber in which the substrate is placed. In many cases, a stage on which the substrate is to be placed is provided at a central portion inside the chamber of the substrate processing apparatus, and in view of limited space and maintenance, an exhaust port is formed at one location near an edge of a bottom surface of the chamber. In this substrate processing apparatus, when the inside of the chamber is decompressed by exhausting an internal atmosphere through the exhaust port at the one location, exhaust characteristics are biased, which causes bias in a substrate processing on the substrate.

Accordingly, a technique for suppressing the bias in the exhaust characteristics has been expected.

### Exemplary Embodiment

[Configuration of Film Forming Apparatus]

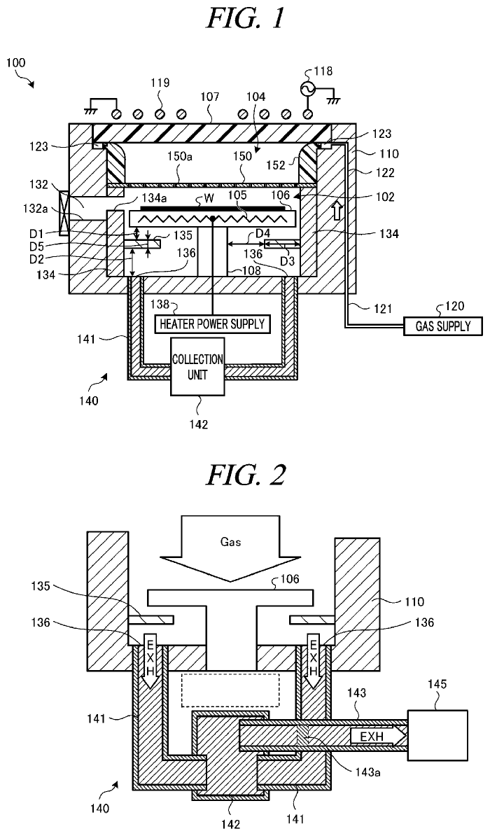

Hereinafter, exemplary embodiments will be described. First, a substrate processing apparatus 100 according to an exemplary embodiment will be described. The substrate processing apparatus 100 performs a substrate processing on a substrate. In the exemplary embodiment, description will be made on an example where the substrate processing apparatus 100 is a plasma processing apparatus and a plasma processing, such as an aching processing, is performed as a substrate processing on the substrate. FIG. 1 is a view schematically showing a configuration example of the substrate processing apparatus 100 according to the exemplary embodiment. The substrate processing apparatus 100 performs a plasma processing, such as an ashing processing for ashing and removing a photoresist film on an etching target film formed on a substrate W, such as a semiconductor wafer.

The substrate processing apparatus 100 includes an airtightly sealed chamber 110. The chamber 110 has a cylindrical shape, and is made of metal, such as aluminum having an anodically oxidized surface, nickel, or the like. An upper portion of the chamber 110 is airtightly closed by an approximately disc-shaped cover body 107 made of an insulating material, such as quartz, ceramic, or the like.

An inside of the chamber 110 is partitioned into a processing chamber 102 and a plasma formation chamber 104 by a partition wall member 150. A plurality of through holes 150a is formed through the partition wall member 150. The plasma formation chamber 104 is provided above the processing chamber 102 via the partition wall member 150. In the plasma formation chamber 104, a gas is excited into plasma by an inductively coupled plasma (ICP) method. The processing chamber 102 communicates with the plasma formation chamber 104 via the plurality of through holes 150a. In the processing chamber 102, a plasma processing, such as an ashing processing, is performed on the substrate W with the plasma supplied through the plurality of through holes 150a.

In the chamber 110, a gas diffusion path 123 is formed at an outer peripheral portion of the cover body 107. The gas diffusion path 123 is formed into a ring shape along an inner circumferential direction of the chamber 110. The gas diffusion path 123 is connected to one end of a gas flow path 122. The gas flow path 122 is formed inside a side wall of the chamber 110. A gas pipe 121 is connected to the other end of the gas flow path 122. The gas pipe 121 is connected to a gas supply 120.

The gas supply 120 is provided with gas supply lines connected to respective gas sources of various gases used for processing the substrate. Each of the gas supply lines is appropriately branched corresponding to the process of the substrate processing, and is provided with a control device configured to control a flow rate of a gas, such as a valve, e.g., an opening/closing valve, and a flow rate controller, e.g., a mass flow controller. The gas supply 120 is configured to supply the various gases used for processing the substrate. In the present exemplary embodiment, description will be made on an example where a mixed gas of a hydrogen (H₂) gas and an argon (Ar) gas is supplied from the gas supply 120. However, the type of the gas is not limited thereto. The gas supplied from the gas supply 120 is introduced into an inner space of the plasma formation chamber 104 from the vicinity of the outer peripheral portion of the cover body 107 via the gas pipe 121, the gas flow path 122 and the gas diffusion path 123.

A coil 119 serving as an antenna member is wound above the chamber 110. A high frequency power supply 118 is connected to the coil 119. The high frequency power supply 118 is configured to output a power of a frequency of 300 kHz to 60 MHz to supply the power to the coil 119. Thus, an induced magnetic field is formed inside the plasma formation chamber 104. In the plasma formation chamber 104, the introduced gas is excited by the induced electromagnetic field so that plasma is generated.

The chamber 110 is provided with a stage 106 on which the substrate W is to be placed. In the substrate processing apparatus 100 according to the present exemplary embodiment, the stage 106 is provided near a central portion inside the processing chamber 102. The stage 106 is supported by a supporting member 108 provided at a bottom portion of the processing chamber 102. The stage 106 is made of aluminum subjected to, for example, alumite treatment. A heater 105 configured to heat the wafer W is embedded in the stage 106. The heater 105 is supplied with a power from a heater power supply 138 so that the substrate W is heated to a predetermined temperature (for example, 300° C.). The heater power supply 138 may control a temperature of the heater 105 in a range of, for example, about 250° C. to about 400° C. so that an etching target film on the substrate W is not greatly damaged.

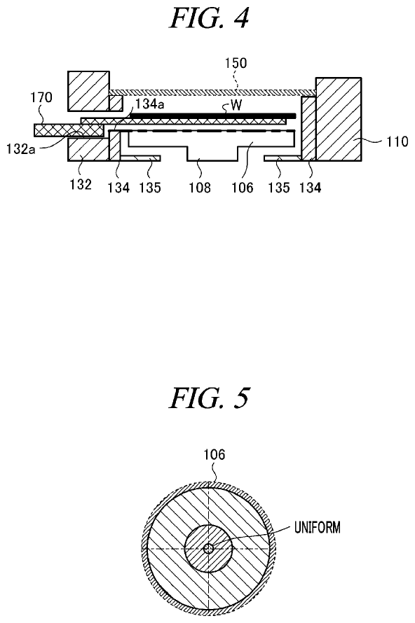

A carry-in/out port 132 for carry-in and carry-out of the substrate W is formed at a side wall of the processing chamber 102. The carry-in/out port 132 is opened/closed by a gate valve 130. The substrate W is carried in and out by a transfer mechanism such as a transfer arm 170 (see FIG. 4). The carry-in/out port 132 has a cross-sectional shape slightly greater than the transfer arm 170 and the substrate W such that the transfer arm 170 and the substrate W can pass through the carry-in/out port 132. For example, a vertical height of the carry-in/out port 132 is greater than a total thickness of the transfer arm 170 and the substrate W by a predetermined tolerance limit. Also, a lower surface 132a of the carry-in/out port 132 is formed lower than an upper surface of the stage 106 such that the carry-in/out port 132 does not interfere with the transfer arm 170 during the carry-in and the carry-out of the substrate W.

A liner 134 configured to protect an inner wall of the processing chamber 102 is provided inside the processing chamber 102. The liner 134 is made of, for example, aluminum. The liner 134 is formed to cover an inner surface of the processing chamber 102. Also, an upper end surface 134a of the liner 134, which is on the side of an inner surface of the lower surface 132a of the carry-in/out port 132, extends higher than the lower surface 132a, and the extended upper end surface 134a is formed at the same height as the upper surface of the stage 106.

The chamber 110 includes a plurality of exhaust ports 136 so as to surround the stage 106. In the present exemplary embodiment, the plurality of exhaust ports 136 is formed in a bottom wall of the chamber 110. Each exhaust port 136 is connected to an exhaust unit 140. The exhaust unit 140 decompresses the inside of the chamber 110 by exhausting the internal atmosphere through the plurality of exhaust ports 136. A detailed configuration of the exhaust unit 140 will be described below. In the substrate processing apparatus 100, the exhaust unit 140 may decompress the inside of the processing chamber 102 and the inside of the plasma formation chamber 104 to a predetermined vacuum degree at which the plasma processing is performed.

A rectifying plate 135, which is protruded from the liner 134 toward the inside, i.e., toward the supporting member 108, is located under the stage 106. The rectifying plate 135 is provided so as to protrude from the liner 134 toward the inside so that the rectifying plate 135 covers an upper portion of each exhaust port 136. The rectifying plate 135 is provided along the entire inner circumference of the liner 134. The rectifying plate 135 has an annular plate shape, and is spaced apart from a lower surface of the stage 106, a circumferential surface of the supporting member 108 and a bottom surface of the chamber 110. The rectifying plate 135 is fixed to a side wall of the chamber 110 and extends from the side wall toward the stage 106. The rectifying plate 135 is a non-hole plate with no hole in an annular plate portion. In the present exemplary embodiment, the rectifying plate 135 corresponds to an annular baffle plate or an annular non-hole baffle plate of the present disclosure. Herein, a distance between the lower surface of the stage 106 and an upper surface of the rectifying plate 135 is D1, and a distance between a lower surface of the rectifying plate 135 and the bottom surface of the chamber 110 is D2. A diametrical length of the annular plate portion of the rectifying plate 135 is D3. A distance between an inner circumferential surface of the rectifying plate 135 and a side surface of the supporting member 108 is D4. A thickness of the rectifying plate 135 is D5. For example, the distance D1 and the distance D2 satisfy a ratio of D1:D2=1:3 to 1:4. Also, the thickness D5 and the distance D1 satisfy D5>D1. Further, the length D3 and the distance D4 satisfy D3>D4.

The plurality of through holes 150a is formed in the partition wall member 150 that partitions between the processing chamber 102 and the plasma formation chamber 104. For example, the partition wall member 150 is provided with the plurality of through holes 150a concentrically formed in sequence from an inner peripheral side. The partition wall member 150 allows radicals of the plasma formed in the plasma formation chamber 104 to pass through the plurality of through holes 150a into the processing chamber 102. That is, when the gas is excited into the plasma in the plasma formation chamber 104, radicals, ions, ultraviolet light and the like are generated. The partition wall member 150 is made of quartz or the like, and shields the ions and the ultraviolet light of the plasma formed in the plasma formation chamber 104 and allows only the radicals to pass through into the processing chamber 102.

A ring-shaped member 152 is provided on a side wall of the plasma formation chamber 104 of the chamber 110 so as to cover the corresponding side wall. The ring-shaped member 152 is made of, for example, quartz. An upper portion of the ring-shaped member 152 is made round, having an inner diameter that gradually decreases toward the inside. An inner wall of the ring-like member 152 is close to the outermost through hole 150a of the partition wall member 150 so as not to block the corresponding through hole 150a.

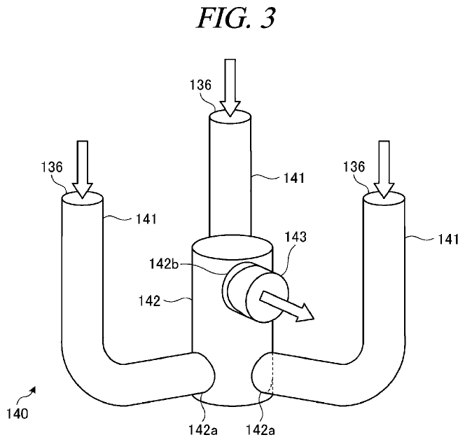

Hereinafter, a configuration of the exhaust unit 140 according to the exemplary embodiment will be described. FIG. 2 is a view schematically showing a configuration example of the exhaust unit 140 according to the exemplary embodiment. FIG. 3 is a perspective view showing the configuration example of the exhaust unit 140 according to the exemplary embodiment.

The plurality of exhaust ports 136 is formed in the bottom wall of the chamber 110 so as to surround the stage 106. The number of exhaust ports 136 may be two or more and desirably three or more. Although FIG. 2 schematically illustrates two exhaust ports 136, the substrate processing apparatus 100 according to the exemplary embodiment is provided with three exhaust ports 136 in the bottom wall of the chamber 110 so as to surround the stage 106. The plurality of exhaust ports 136 is equally spaced around the stage 106. For example, in the present exemplary embodiment, three exhaust ports 136 are spaced apart at an angle of 120° around the center of the stage 106.

The exhaust unit 140 has a manifold structure connected to each of the plurality of exhaust ports 136. For example, the exhaust unit 140 is provided with a plurality of first pipes 141, a collection unit 142 and a second pipe 143. One end of each of the plurality of first pipes 141 is connected to the corresponding exhaust port 136. The collection unit 142 has a cylindrical shape having a hollow inner space. The other ends of the plurality of first pipes 141 are connected to a lower side surface of the collection unit 142. The plurality of first pipes 141 communicates with the hollow inner space of the collection unit 142. The second pipe 143 is connected to a side surface of the collection unit 142 at a position higher than the connection positions between the other ends of the plurality of first pipes 141 and the collection unit 142. A lower end of the second pipe 143 at the connection position between the second pipe 143 and the collection unit 142 is higher than upper ends of the other ends of the plurality of first pipes 141 at the connection positions between the other ends of the plurality of first pipes 141 and the collection unit 142. The second pipe 143 communicates with the hollow inner space of the collection unit 142. The second pipe 143 is provided with a pressure control valve 143a, such as an auto pressure controller (APC) valve or the like. The other end of the second pipe 143 is connected to an exhaust system, such as exhaust device, e.g., a vacuum pump, and a factory exhaust pipe. In the example shown in FIG. 2, a vacuum pump 145 serving as the exhaust system is connected to the other end of the second pipe 143. For example, as shown in FIG. 3, a side wall of the collection unit 142 has a plurality of first openings 142a and a second opening 142b located above the plurality of first openings 142a. The plurality of first pipes 141 is connected to the plurality of first openings 142a and extends from the plurality of first openings 142a to the plurality of exhaust ports 136, respectively. The second pipe 143 is connected to the second opening 142b and extends from the second opening 142b to the vacuum pump 145.

Since the exhaust system performs an exhaust operation via the second pipe 143, the exhaust unit 140 exhausts the internal atmosphere of the chamber 110 via the collection unit 142 and the plurality of first pipes 141. Also, since the pressure control valve 143a provided in the second pipe 143 regulates an exhaust pressure, the exhaust unit 140 controls a pressure inside the chamber 110.

[Sequence of Substrate Processing]

Hereinafter, a sequence of a plasma processing performed as the substrate processing by the substrate processing apparatus 100 according to the exemplary embodiment will be described. When the plasma processing is performed on the substrate W, the gate valve 130 is opened. A transfer mechanism, such as the transfer arm 170, carries the substrate W into the processing chamber 102 through the carry-in/out port 132 and places the substrate W on the stage 106. FIG. 4 schematically shows a carry-in of the substrate W into the substrate processing apparatus 100 according to the exemplary embodiment.

Herein, the carry-in/out port 132 has a cross-sectional shape slightly greater than the transfer arm 170 and the substrate W so that the transfer arm 170 and the substrate W can pass through the carry-in/out port 132. Also, the lower surface 132a of the carry-in/out port 132 is formed lower than the upper surface of the stage 106 so that the carry-in/out port 132 does not interfere with the transfer arm 170. Accordingly, like a multi-joint arm that is extended and contracted by horizontally rotating a plurality of arms, even if a housing of the transfer arm 170 protrudes downwards by a front side arm, it is possible to suppress the interference between the carry-in/out port 132 and the transfer arm 170 during the carry-in of the substrate W.

When the carry-in of the substrate W is completed, the gate valve 130 is closed. The exhaust unit 140 decompresses the inside of the processing chamber 102 and the inside of the plasma formation chamber 104 to a predetermined pressure by exhausting the internal atmosphere thereof through the exhaust ports 136. Also, the heater power supply 138 supplies a predetermined power to the heater 105 so that the substrate W is heated to a predetermined temperature (for example, 300° C.).

Then, the gas supply 120 supplies a hydrogen gas and an argon gas into the plasma formation chamber 104 via the gas pipe 121, the gas flow path 122 and the gas diffusion path 123. Also, the high frequency power supply 118 supplies the high frequency power of, for example, 4000 W to the coil 119 so that an induced electromagnetic field is formed inside the plasma formation chamber 104. Thus, in the plasma formation chamber 104, plasma is formed from the hydrogen gas and the argon gas. The partition wall member 150 shields the ultraviolet light and the ions of the formed plasma and allows the radicals to pass through. Accordingly, the surface of the substrate W inside the processing chamber 102 is not damaged by the ultraviolet light and the ions, and a desired processing, such as an aching processing on the photoresist film on the substrate, may be performed with the radicals.

Here, as shown in FIG. 1 to FIG. 3, in the substrate processing apparatus 100 according to the exemplary embodiment, three exhaust ports 136 are equally spaced to surround the stage 106 and the internal atmosphere of the chamber 110 is exhausted through each of the exhaust ports 136. Accordingly, an exhaust flow to each of the exhaust ports 136 is distributed in the circumferential direction of the stage 106, and, thus, it is possible to suppress bias in exhaust characteristics. Also, in the substrate processing apparatus 100 according to the exemplary embodiment, the rectifying plate 135 is provided around and under the stage 106 so as to cover each of the exhaust ports 136. Accordingly, the exhaust flow to each of the exhaust ports 136 passes through a space surrounded by the rectifying plate 135, the lower surface of the stage 106 and the circumferential surface of the supporting member 108. Thus, the exhaust flow is diffused to be made uniform in the circumferential direction of the stage 106. Therefore, it is possible to further suppress the bias in the exhaust characteristics.

Also, as shown in FIG. 1 and FIG. 2, in the substrate processing apparatus 100 according to the exemplary embodiment, the upper end surface 134a of the liner 134 extends higher than the lower surface 132a of the carry-in/out port 132 and is formed at the same height as the upper surface of the stage 106. The upper end surface 134a of the liner 134 may be formed higher than the upper surface of the stage 106. As such, only the innermost side of a bottom surface of an opening of the carry-in/out port 132 has the same height as the upper surface of the stage 106, and, thus, conductance for each of the exhaust ports 136 located thereunder can be made uniform in the circumferential direction of the stage 106. Therefore, uniformity of the gas can be improved. Further, only the upper end surface 134a of the liner 134 extends upwards, and, thus, only the inside of the carry-in/out port 132 is narrowed. Accordingly, the carry-in/out port 132 can secure a space into which the transfer arm 170 is introduced.

FIG. 5 shows exhaust characteristics of the substrate processing apparatus 100 according to the exemplary embodiment. FIG. 5 shows the result of simulation of the exhaust characteristics in the configuration of the substrate processing apparatus 100 according to the exemplary embodiment. FIG. 5 shows the distribution of in-plane exhaust characteristics of the stage 106. The substrate processing apparatus 100 according to the exemplary embodiment can suppress the bias in the exhaust characteristics. Therefore, as shown in FIG. 5, the in-plane exhaust characteristics of the stage 106 can be made uniform.

Also, in the exhaust unit 140 according to the exemplary embodiment, each first pipe 141 connected to the corresponding exhaust port 136 is connected to the collection unit 142, and the second pipe 143 is connected to the collection unit 142 at the position higher than the connection positions between the first pipes 141 and the collection unit 142. Accordingly, for example, even if foreign substances, such as screws, fall into the first pipes 141 from the exhaust ports 136 and reach the hollow inner space of the collection unit 142, it is possible to suppress introduction of the foreign substances into the second pipe 143.

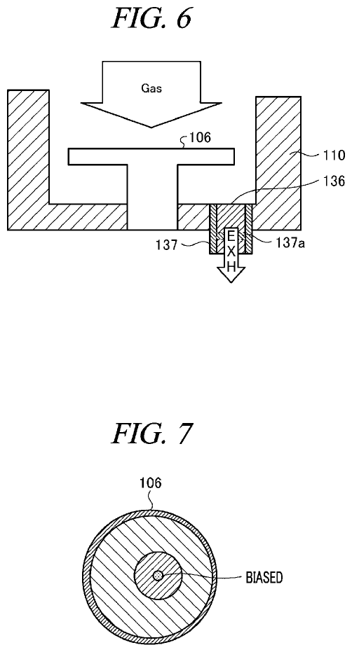

Hereinafter, a conventional substrate processing apparatus will be described as a comparative example. In the conventional substrate processing apparatus, a stage on which a substrate is to be placed is provided at a central portion inside a chamber, and in view of limited space and maintenance, an exhaust port is formed at one location near an edge of a bottom surface of the chamber. FIG. 6 is a view schematically showing a configuration of a substrate processing apparatus according to a comparative example. In FIG. 6, the same component as that of the substrate processing apparatus 100 according to the exemplary embodiment will be assigned the same reference numeral. In the substrate processing apparatus according to the comparative example, the exhaust port 136 is provided at one location in the bottom wall of the chamber 110. In this case, exhaust characteristics are biased on the side of the exhaust port 136 inside the chamber 110. FIG. 7 shows exhaust characteristics of the substrate processing apparatus according to the comparative example. FIG. 7 shows the result of simulation of exhaust characteristics when the exhaust port 136 is provided at one location in the bottom wall of the chamber 110. FIG. 7 shows the distribution of in-plane exhaust characteristics of the stage 106. As shown in FIG. 7, in the substrate processing apparatus according to the comparative example, the distribution of in-plane exhaust characteristics of the stage 106 is biased. If the exhaust characteristics are biased as such, a gas is biased in the in-plane of the stage 106. Therefore, when the substrate W is processed, in-plane processing characteristics of the substrate W are biased.

Also, in the conventional substrate processing apparatus, the exhaust port 136 is provided in the bottom wall of the chamber 110 as shown in FIG. 6. Therefore, foreign substances, such as screws, may be introduced from the exhaust port 136 into a pipe 137 connected to the exhaust port 136. The pipe 137 is provided with a pressure control valve 137a, such as an APC valve or the like. The pressure control valve 137a cannot control an exhaust operation when the foreign substances are introduced into the pressure control valve 137a. For this reason, in the conventional substrate processing apparatus, the exhaust port 136 needs to be provided with a net for suppressing the introduction of the foreign substances. However, a reaction product may adhere to the net for suppressing the introduction of the foreign substances and may be gradually accumulated thereon, which cause degradation in the exhaust characteristics.

Meanwhile, since the substrate processing apparatus 100 according to the exemplary embodiment can suppress the bias in the exhaust characteristics, it is possible to suppress the bias of gas in the in-plane of the stage 106. Therefore, when the substrate W is processed, it is possible to suppress the bias in in-plane processing characteristics of the substrate W.

Further, the exhaust unit 140 according to the exemplary embodiment can suppress the introduction of the foreign substances into the exhaust system without the net for suppressing the introduction of the foreign substances into the first pipes 141, the collection unit 142 and the second pipe 143. As described above, the exhaust unit 140 according to the exemplary embodiment does not need to be provided with the net for suppressing the introduction of the foreign substances and thus can suppress the degradation in the exhaust characteristics.

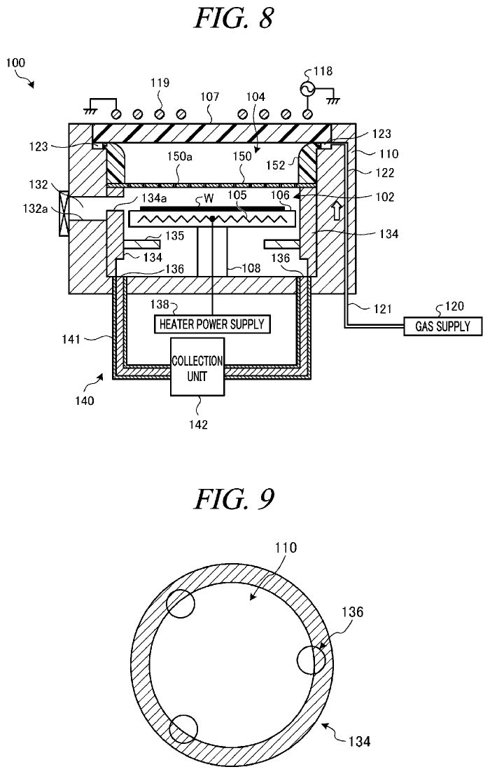

In the above-described exemplary embodiment, description has been made on a case where the plurality of exhaust ports 136 is formed in the bottom portion of the chamber 110. However, the present disclosure is not limited thereto. Some of the plurality of exhaust ports 136 may be formed in the bottom portion of the chamber 110 and the others of the plurality of exhaust ports 136 may be formed in the side wall of the chamber 110. Also, all of the plurality of exhaust ports 136 may be formed in the side wall of the chamber 110. Further, some or all of the plurality of exhaust ports 136 may be formed from the bottom surface to the side wall of the chamber 110. FIG. 8 is a view schematically showing another configuration example of the substrate processing apparatus 100 according to the exemplary embodiment. FIG. 9 is a view schematically showing an arrangement example of the exhaust ports 136 at the bottom wall portion of the chamber 110 according to the exemplary embodiment. The substrate processing apparatus 100 shown in FIG. 8 and FIG. 9 has some components which are the same as those of the substrate processing apparatus 100 shown in FIG. 1, and the same components will be assigned the same reference numerals. Therefore, redundant descriptions will be omitted, and description will be mainly made on different components. FIG. 8 and FIG. 9 show a case where the plurality of exhaust ports 136 is formed at a corner between the liner 134 and the bottom surface of the chamber.

As shown in FIG. 8, in the substrate processing apparatus 100, the exhaust ports 136 are formed under the liner 134 at corners between the bottom surface of the chamber 110 and the liner 134. A plurality of exhaust ports 136 may be formed to surround the stage 106. The plurality of exhaust ports 136 may be formed in a side surface of the liner 134 so as to surround the stage 106. As shown in FIG. 9, the exhaust ports 136 are formed so that the outside of each opening is located under the liner 134. That is, the outside of each exhaust port 136 is located under the liner 134. A lower inner surface of the liner 134 corresponding in position to each exhaust port 136 has a recess corresponding in shape to each exhaust port 136. Accordingly, the exhaust port 136 can suction air even through the outside of the exhaust port 136 located under the liner 134. In the exhaust unit 140, upper portions of the first pipes 141 are connected to the exhaust ports 136, respectively. The exhaust unit 140 exhausts the internal atmosphere of the chamber 110 via the collection unit 142 and the plurality of first pipes 141 by performing the exhaust operation in the exhaust system via the second pipe 143. Also, the exhaust unit 140 controls the pressure inside the chamber 110 by regulating the exhaust pressure with the pressure control valve 143a provided in the second pipe 143. As described above, in the substrate processing apparatus 100 according to the exemplary embodiment, the plurality of exhaust ports 136 may be provided in the side surface of the liner 134 to exhaust the internal atmosphere of the chamber 110.

[Effect]

As described above, the substrate processing apparatus 100 according to the exemplary embodiment includes the chamber 110, the stage 106 (substrate support), the rectifying plate 135 (annular baffle plate), the vacuum pump 145 and the exhaust unit 140 (pipe unit). The chamber 110 has a side wall and a bottom portion, and is provided with at least one gas supply port (the gas diffusion path 123) and the plurality of exhaust ports 136. In the chamber 110, some or all of the plurality of exhaust ports 136 are formed in the bottom portion of the chamber 110. The stage 106 is placed inside the chamber 110. The rectifying plate 135 is placed near the stage 106 to cover the plurality of exhaust ports 136 when viewed from the top, and a gap is formed between the rectifying plate 135 and the stage 106. The exhaust unit 140 includes the collection unit 142 (collection pipe unit), the plurality of first pipes 141 and the second pipe 143. The collection unit 142 has a side wall. The side wall of the collection unit 142 is provided with the plurality of first openings 142a and the second opening 142b located above the plurality of first openings 142a. The plurality of first pipes 141 extends from the plurality of first openings 142a to the plurality of exhaust ports 136, respectively. The second pipe 143 extends from the second opening 142b to the vacuum pump 145. Accordingly, the substrate processing apparatus 100 can suppress the bias in the exhaust characteristics.

Further, the chamber 110 has three or more exhaust ports 136. Thus, the substrate processing apparatus 100 can distribute the exhaust flow to each of the exhaust ports 136. Therefore, it is possible to suppress the bias in the exhaust characteristics.

Furthermore, the plurality of exhaust ports 136 is equally spaced in the circumferential direction. Thus, the substrate processing apparatus 100 can distribute the exhaust flow to each of the exhaust ports 136 in the circumferential direction of the stage 106. Therefore, it is possible to suppress the bias in the exhaust characteristics.

Moreover, the rectifying plate 135 extends from the side wall of the chamber 110 toward the stage 106. Thus, the substrate processing apparatus 100 can distribute the exhaust flow to each of the exhaust ports 136 in the circumferential direction by the rectifying plate 135. Therefore, it is possible to suppress the bias in the exhaust characteristics.

Also, the stage 106 includes a substrate supporting plate (a plate portion of the stage 106) having a first diameter and a leg member (the supporting member 108) having a second diameter, which is smaller than the first diameter, and extending downwards from a lower surface of the substrate supporting plate. The rectifying plate 135 has an inner diameter which is smaller than the first diameter. Thus, in the substrate processing apparatus 100, the exhaust flow to each of the exhaust ports 136 is curved to be diffused. Therefore, it is possible to further suppress the bias in the exhaust characteristics.

Further, the rectifying plate 135 has a width which is greater than the gap. Thus, the substrate processing apparatus 100 can diffuse the exhaust flow to each of the exhaust ports 136 in the circumferential direction by the rectifying plate 135. Therefore, it is possible to further suppress the bias in the exhaust characteristics.

The exemplary embodiments disclosed herein are illustrative in all aspects and do not limit the present disclosure. In fact, the above exemplary embodiments can be embodied in various forms. Further, the above-described exemplary embodiments may be omitted, substituted, or changed in various forms without departing from the scope and spirit of the appended claims.

For example, in the above-described exemplary embodiment, description has been made on the case where the substrate processing is the aching processing. However, the present disclosure is not limited thereto. Any substrate processing by which the inside of the chamber 110 is decompressed may be applied. For example, the substrate processing may be a plasma processing, such as plasma etching, or a processing without using plasma. Further, the substrate processing may be an etching processing or a film forming processing.

For example, in the above-described exemplary embodiment, description has been made on the case where the plurality of exhaust ports 136 is formed in the bottom wall of the chamber 110. However, the present disclosure is not limited thereto. The plurality of exhaust ports 136 may be formed in the side wall of the chamber 110 at a position lower than the upper surface of the stage 106.

Further, in the above-described exemplary embodiment, description has been made on the case where the substrate processing apparatus 100 is the so-called inductively coupled plasma (ICP) apparatus. However, the present disclosure is not limited thereto. The substrate processing apparatus 100 may be any apparatus as long as it performs a substrate processing by decompressing the inside of the chamber 110. For example, the substrate processing apparatus 100 may be an apparatus using capacitively-coupled plasma (CCD), electron-cyclotron-resonance (ECR) plasma, helicon wave plasma (HWP) or surface wave plasma (SWP).

Furthermore, in the above-described exemplary embodiment, description has been made on the example where the substrate W is the semiconductor wafer. However, the present disclosure is not limited thereto. The substrate W may be any type of substrate.

The exemplary embodiments disclosed herein are illustrative in all aspects and do not limit the present disclosure. In fact, the above exemplary embodiments can be embodied in various forms. Further, the above-described exemplary embodiments may be omitted, substituted, or changed in various forms without departing from the scope and spirit of the appended claims.

According to the present disclosure, it is possible to suppress the bias in the exhaust characteristics.

From the foregoing, it will be appreciated that various exemplary embodiments of the present disclosure have been described herein for purposes of illustration and various changes can be made without departing from the scope and spirit of the present disclosure. Accordingly, various exemplary embodiments described herein are not intended to be limiting, and the true scope and spirit are indicated by the following claims.

We claim:

1. A substrate processing apparatus, comprising:
a chamber, having a side wall and a bottom portion, provided with at least one gas supply port and multiple exhaust ports, some or all of the multiple exhaust ports being formed in the bottom portion of the chamber;
a substrate support placed inside the chamber;
an annular baffle plate placed near the substrate support to cover the multiple exhaust ports when viewed from a top, a gap being formed between the annular baffle plate and the substrate support;
a vacuum pump; and
a pipe unit,
wherein the pipe unit includes:
a collection pipe unit having a side wall, the side wall being provided with multiple first openings and a second opening located above the multiple first openings;
multiple first pipes extending from the multiple first openings to the multiple exhaust ports, respectively; and
a second pipe extending from the second opening to the vacuum pump.

2. The substrate processing apparatus of claim 1,
wherein the multiple exhaust ports include three or more exhaust ports.

3. The substrate processing apparatus of claim 1,
wherein the multiple exhaust ports are equally spaced in a circumferential direction.

4. The substrate processing apparatus of claim 1,
wherein the annular baffle plate extends from the side wall of the chamber toward the substrate support.

5. The substrate processing apparatus of claim 1,
wherein the substrate support includes:
a substrate supporting plate having a first diameter; and
a leg member having a second diameter, which is smaller than the first diameter, and extending downwards from a lower surface of the substrate supporting plate.

6. The substrate processing apparatus of claim 5,
wherein the annular baffle plate has an inner diameter which is smaller than the first diameter.

7. The substrate processing apparatus of claim 1,
wherein the annular baffle plate has a width which is greater than the gap.

8. The substrate processing apparatus of claim 1,
wherein some of the multiple exhaust ports are formed in the side wall of the chamber.

9. The substrate processing apparatus of claim 1,
wherein the annular baffle plate is a non-hole plate.

10. A substrate processing apparatus, comprising:
a chamber, having a side wall and a bottom portion, provided with at least one gas supply port and multiple exhaust ports, the multiple exhaust ports being formed in the side wall of the chamber;
a substrate support placed inside the chamber;
an annular non-hole baffle plate located above the multiple exhaust ports to extend from the side wall of the chamber toward the substrate support, a gap being formed between the annular non-hole baffle plate and the substrate support;
a vacuum pump; and
a pipe unit,
wherein the pipe unit includes:
a collection pipe unit having a side wall, the side wall being provided with multiple first openings and a second opening located above the multiple first openings;
multiple first pipes extending from the multiple first openings to the multiple exhaust ports, respectively; and
a second pipe extending from the second opening to the vacuum pump.

11. A substrate processing apparatus, comprising:
a chamber provided with at least one gas supply port and multiple exhaust ports;
a substrate support placed inside the chamber;
a vacuum pump; and
a pipe unit,
wherein the pipe unit includes:
a collection pipe unit having a side wall, the side wall being provided with multiple first openings and a second opening located above the multiple first openings;
multiple first pipes extending from the multiple first openings to the multiple exhaust ports, respectively; and
a second pipe extending from the second opening to the vacuum pump.
